(19) United States
(12) Patent Application Publication
(10) Pub. No.: US 2025/0024640 A1
(43) Pub. Date: Jan. 16, 2025

(54) HYBRID COOLING SYSTEMS TO COOL MULTI-CHIP MODULES

(71) Applicant: CoolIT Systems, Inc., Calgary (CA)

(72) Inventors: Mohammad Reza Najjari, Calgary (CA); Cameron S. Turner, Calgary (CA); Jarod Domingo, Calgary (CA); Bradley Zakaib, Calgary (CA)

(21) Appl. No.: 18/772,205

(22) Filed: Jul. 14, 2024

Related U.S. Application Data
(60) Provisional application No. 63/526,917, filed on Jul. 14, 2023.

(51) Int. Cl. H05K 7/20

(52) U.S. Cl. CPC H05K 7/20318

(57) ABSTRACT

A hybrid cooler has a first condenser block and a second condenser block. A liquid-cooled cold plate has opposed first and second external major surfaces and an internal passageway to direct a flow of coolant through the liquid-cooled cold plate to cool the opposed first and second external major surfaces. The internal passageway is fluidically coupled with the first condenser block and the second condenser block. The hybrid cooler has a first passive cold plate and a second passive cold plate, each extending from the first condenser block to the second condenser block. Each of the first passive cold plate and the second passive cold plate has a respective major surface positioned opposite the opposed first and second external major surfaces of the liquid-cooled cold plate. The liquid-cooled cold plate is positioned between the first passive cold plate and the second passive cold plate.

### FIELD

This application and the subject matter disclosed herein (collectively referred to as the “disclosure”), generally concern hybrid cooling systems, together with associated components and methods. More particularly, but not exclusively, this disclosure pertains to liquid-cooling systems incorporating passive cooling components (e.g., two-phase-cooling components), together with related methods and devices suited to cool multi-chip modules, such as, for example, memory modules having a plurality of memory and other components mounted to one or both sides of a substrate. For example, such a substrate can include a printed circuit board, which may be generally planar or may have a plurality of component mounting surfaces at a corresponding plurality of elevations from a reference plane. A passive cold plate (e.g., a plate of metal or a vapor chamber) can span across the plurality of components and facilitate heat transfer from the components to a liquid-cooling loop. In some embodiments, a liquid-cooled cold plate also spans across a plurality of components and facilitates heat transfer from the components to a liquid-cooling loop.

### BACKGROUND INFORMATION

New generations of electronic components, such as, for example, memory components, microprocessors, graphics processors, and power electronics semiconductor devices, produce increasing amounts of heat during their operation. If the heat is not removed at a sufficient rate, the components can overheat, decreasing performance, reliability, or both, and in some cases component damage or failure.

Electronic devices, such as, for example, servers, computers, game consoles, power electronics, communications and other networking devices, batteries, and so on, can use air cooling, liquid cooling (e.g., involving one- or two-phases with say, water or refrigerant, respectively), or both, to transfer and dissipate heat from electronic components to an ultimate heat sink, e.g., the atmosphere. Conventional air cooling relies on natural convection or uses forced convection (e.g., a fan mounted near a heat producing component) to replace heated air with cooler ambient air around the component. Such air-cooling techniques can be supplemented with a conventional “heat sink,” which often is a plate of a thermally conductive material (e.g., aluminum or copper) placed in thermal contact with the heat-producing component. The heat sink can spread heat from the component to a larger area for dissipating heat to the surrounding air. Some heat sinks include “fins” to further increase the surface area available for heat transfer and thereby to improve the transfer of heat to the air. Some heat sinks include a fan to force air among the fins and are commonly referred to in the art as “active” heat sinks.

### SUMMARY

Liquid cooling improves cooling performance compared to air cooling techniques described above, as many liquids, e.g., water, have significantly better heat transfer capabilities than air. FIG. 1 illustrates various components of a liquid cooling loop 100. The cooling loop 100 typically operates by (1) transferring heat, \dot{Q}ᵢₙ, from a heat-generating electronic component (not shown) to a cool liquid passing through a heat exchanger 110 (sometimes referred to in the art as a “cold plate” or a “heat sink”) placed in thermal contact with the heat-generating component, (2) transporting the heat absorbed by the liquid to a remote radiator 120, or heat rejector (sometimes referred to in the art generally as a “heat exchanger,” or a “liquid-to-liquid heat exchanger” if the heat is rejected to another liquid or a “liquid-to-air heat exchanger” if the heat is rejected to air), (3) dissipating the heat, \dot{Q}ₒᵤₜ, from the remote radiator to another medium (e.g., air or facility water passing through the remote radiator), and (4) returning cooled liquid to the heat exchanger (or heat sink).

Presently disclosed cooling devices and systems provide further improved thermal performance for multi-chip modules and their components compared to previously proposed cooling devices and systems. As but one illustrative example, one or more passive cold plates, e.g., a sheet or plate of metal or other thermally conductive material, or \a passive, two-phase, or “vapor-chamber,” cold plates, heat-pipe cold plates, etc., can thermally couple with one or more pluralities of DRAM or other components mounted to a memory module, e.g., a dual inline memory module, sometimes referred to in the art as a DIMM, to enhance cooling of the components by transferring heat from the components to a liquid flowing through a cooling loop. In some disclosed embodiments, a liquid-cooled condenser block is configured to conductively receive heat from a plurality of passive, two-phase cold plates, e.g., vapor-chamber cold plates, flattened heat-pipe cold plates, or a combination thereof, and to facilitate transfer of that heat to a liquid coolant flowing through the condenser block.

According to a first aspect, a disclosed liquid cooling system has a pair of opposed condenser blocks. Each condenser block defines an internal fluid passage and the internal fluid passage has a first port and a second port. A liquid-cooled cold plate has a first end and an opposed second end, opposed first and second major surfaces, and an internal passageway positioned between the opposed first and second major surfaces. The liquid-cooled cold plate extends from the first end to the opposed second end. The first port of each condenser block is configured to fluidically couple with a coolant supply or a coolant collector. The second port of one of the condenser blocks fluidically couples with the first end of the liquid-cooled cold plate and the second port of the other of the condenser blocks so fluidically couples with the second end of the liquid-cooled cold plate that liquid-cooled cold plate extends from one in the pair of opposed condenser blocks to the other in the pair of opposed condenser blocks. A passive cold plate has a first major surface positioned opposite and spaced apart from the first major surface of the liquid-cooled cold plate, defining a gap therebetween. The gap is sized to receive a multi-chip module to be cooled by the liquid cooling system. The passive cold plate extends from a first end to an opposed second end. One of the opposed condenser blocks defines a recessed slot configured to receive the first end of the passive cold plate and the other of the opposed condenser blocks defines a recessed slot configured to receive the second end of the passive cold plate.

In an embodiment of such a cooling system, the passive cold plate is a first passive cold plate, and the multi-chip module to be cooled by the liquid cooling system is a first multi-chip module to be cooled by the liquid cooling system. In an embodiment, the liquid cooling system also includes a second passive cold plate having a first major surface positioned opposite and spaced apart from the second major surface of the liquid-cooled cold plate, defining a gap therebetween. That gap is sized to receive a second multi-chip module to be cooled by the liquid cooling system. The second passive cold plate can extend from a first end to an opposed second end. One of the opposed condenser blocks can define a recessed slot configured to receive the first end of the second passive cold plate. The other of the opposed condenser blocks can define a recessed slot configured to receive the second end of the second passive cold plate.

The first passive cold or the second passive cold plate, or both, can be a passive, two-phase cold plate. Each passive, two-phase cold plate can have a condenser region positioned adjacent the first end and the second end of the respective two-phase cold plate. The opposed condenser blocks can receive heat from each condenser region.

Some embodiments of such cooling systems include clip configured to compress the first and second passive cold plates, the first and second multi-chip modules and liquid-cooled cold plate together. Such compression can enhance thermal contact between surfaces.

The liquid-cooled cold plate can be a first liquid-cooled cold plate and the liquid cooling system can include a second liquid-cooled cold plate having an internal passageway fluidically coupled with the opposed condenser blocks. The second liquid-cooled cold plate can have a first end and an opposed second end, and opposed first and second major surfaces. The internal passageway of the second liquid-cooled cold plate can be positioned between the opposed first and second major surfaces of the second liquid-cooled cold plate and extends from the first end of the second liquid-cooled cold plate to the opposed second end of the second liquid-cooled cold plate.

Some embodiments include a third passive cold plate having a first major surface positioned opposite and so spaced apart from the first major surface of the second liquid-cooled cold plate as to define a gap sized to receive a third multi-chip module to be cooled by the liquid cooling system. Some embodiments also include a fourth passive cold plate. Such a fourth passive cold plate can have a first major surface positioned opposite and so spaced apart from the second major surface of the second liquid-cooled cold plate as to define a gap sized to receive a fourth multi-chip module to be cooled by the liquid cooling system.

A liquid cooling system can include a first thermal interface material positioned in contact with the first major surface major surface of the passive cold plate. A second thermal interface material can be positioned in contact with the first major surface of the liquid-cooled cold plate. The first thermal interface material and the second thermal interface material can be configured to provide thermal contact between opposed faces of the multi-chip module to be cooled by the cooling system and the respective first major surfaces of the passive cold plate and the liquid-cooled cold plate.

According to a second aspect, hybrid coolers are disclosed. Such a hybrid cooler can include a first condenser block and a second condenser block. A liquid-cooled cold plate has opposed first and second external major surfaces and an internal passageway to direct a flow of coolant through the liquid-cooled cold plate to cool the opposed first and second external major surfaces. The internal passageway can be fluidically coupled with the first condenser block and the second condenser block. Such a hybrid cooler can include a first passive cold plate and a second passive cold plate. Each of the first passive cold plate and the second passive cold plate can extend from the first condenser block to the second condenser block. Each of the first passive cold plate and the second passive cold plate can have a respective major surface positioned opposite the opposed first and second external major surfaces of the liquid-cooled cold plate. The liquid-cooled cold plate can be positioned between the first passive cold plate and the second passive cold plate.

The first passive cold plate can be so spaced apart from the liquid-cooled cold plate as to define a first gap therebetween. The second passive cold plate can be so spaced apart from the liquid-cooled cold plate as to define a second gap therebetween. The first gap and the second gap can be so sized as to receive a first multi-chip module and a second multi-chip module, respectively.

The liquid-cooled cold plate can be a first liquid-cooled cold plate, and the hybrid cooler can also include a second liquid-cooled cold plate, as well as a third passive cold plate. The second liquid-cooled cold plate can be positioned between the third passive cold plate and one of the first passive cold plate and the second passive cold plate. The third passive cold plate can be so spaced apart from the second liquid-cooled cold plate as to define a gap therebetween. Such a gap can be so sized as to receive a multi-chip module.

A hybrid cooler can also include a fourth passive cold plate so spaced apart from the second liquid cooler as to define a gap therebetween. The gap can be sized to receive a multi-chip module.

The first condenser block can have an inlet port and the second condenser block can have an outlet port. The inlet port can be a first inlet port and the first condenser block can also have a second inlet port. Similarly, the outlet port can be a first outlet port, and the second condenser block can also have a second outlet port. In some embodiments, the first condenser block has an an inlet port and an outlet port for the hybrid cooler.

The foregoing and other features and advantages will become more apparent from the following detailed description, which proceeds with reference to the accompanying drawings.

### BRIEF DESCRIPTION OF THE DRAWINGS

Referring to the drawings, wherein like numerals refer to like parts throughout the several views and this specification, aspects of presently disclosed principles are illustrated by way of example, and not by way of limitation.

FIG. 1 illustrates a closed liquid-cooling loop.

FIG. 2 illustrates an isometric view of a multi-chip module cooled by opposed passive, two-phase (e.g., vapor-chamber or heat-pipe) cold plates and a liquid-cooled condenser block.

FIG. 3 illustrates a longitudinal cross-section of the assembly shown in FIG. 2, which reveals one of the passive, two-phase cold plates with its ends thermally coupled with a liquid-cooled condenser block.

FIG. 4 illustrates another longitudinal cross-section of the assembly shown in FIG. 2 revealing a circuit-board substrate, to each side of which a plurality of memory devices is mounted.

FIG. 5 illustrates yet another longitudinal cross-section of the assembly shown in FIG. 2 revealing a plurality of the memory devices mounted to the circuit-board substrate shown in FIG. 4.

FIG. 6 illustrates still another longitudinal cross-section of the assembly shown in FIG. 2 revealing a thermal-interface material overlying the memory devices shown in FIG. 5.

FIG. 7 schematically illustrates a multi-chip module cooled as shown in FIG. 2, with a partially enlarged view showing detail of the thermal boss and its thermal contact with non-memory heat-generating components.

FIG. 7A schematically illustrates an exploded view of a passive, two-phase cold plate as in FIGS. 2 through 7, 8 and 9.

FIG. 8 illustrates an embodiment of a passive, two-phase cold plate having a thermal boss, e.g., to provide thermal contact with one or more heat-generating components having a height (from the circuit-board substrate) different from the plurality of memory components, e.g., shown in FIG. 5.

FIG. 9 is a photograph showing a working embodiment of a vapor-chamber cold plate, similar to the passive, two-phase cold plate shown in FIG. 8.

FIG. 10 illustrates an alternative embodiment of a passive, two-phase (e.g., vapor-chamber) cold plate having an out-of-plane region adapted to provide thermal contact with one or more heat-generating components having a height (from the circuit-board substrate) different from the plurality of memory components, e.g., as shown in FIG. 5.

FIG. 11 illustrates yet another alternative embodiment of a passive, two-phase (e.g., a flattened heat pipe) cold plate having an out-of-plane region adapted to provide thermal contact with one or more heat-generating components having a height (from the circuit-board substrate) different from the plurality of memory components, e.g., as shown in FIG. 5.

FIG. 12 is a photograph showing a working embodiment of a cooling system as shown in FIGS. 2 and 9 applied to a thermal test vehicle.

FIG. 13 is another photograph showing the working embodiment in FIG. 12.

FIG. 14 is a photograph showing another working embodiment of a cooling system similar to that shown in FIG. 12.

FIG. 15 is a photograph showing the thermal test vehicle and a pair of vapor-chamber cold plates removed from the cooling system shown in FIG. 14. In FIG. 15, thermal-interface material is shown on the exposed end regions (condenser regions) of the vapor-chamber cold plates.

FIG. 16, like FIG. 2, illustrates an isometric view of opposed passive, two-phase (e.g., vapor-chamber or heat-pipe) cold plates and liquid-cooled condenser blocks. FIG. 16 shows an embodiment configured to cool, in this example, four multi-chip modules compared to the single multi-chip module shown in FIG. 2.

FIG. 17 shows a plan view from above the embodiment shown in FIG. 16.

FIG. 18 illustrates another embodiment for cooling a plurality of multi-chip modules. In FIG. 18, each pair of multi-chip modules is cooled by a central, liquid-cooled cold plate fluidically coupled with the liquid-cooled condenser blocks, as well as flanking passive, two-phase cold plates thermally coupled with the liquid-cooled condenser blocks.

FIG. 19 shows a plan view from above the embodiment shown in FIG. 18.

FIG. 20 shows a longitudinal cross-section taken along plane XX-XX shown in FIG. 18.

FIG. 21 shows the embodiment in FIG. 18 with the clip and one of the liquid-cooled condenser blocks removed to reveal additional internal detail.

FIG. 22 shows a portion of the embodiment shown in FIG. 18.

FIG. 23 shows the clip from FIG. 18.

FIG. 24 shows the embodiment portion depicted in FIG. 22, but with the clip shown in FIG. 23 removed.

FIG. 25 shows the embodiment portion depicted in FIG. 24, albeit with a passive, two-phase cold plate removed to reveal a side of one of the multi-chip modules.

FIG. 26 shows the embodiment portion depicted in FIG. 25 with the multi-chip module removed to reveal a central, liquid-cooled cold plate.

FIG. 27 shows an isometric view of a liquid-cooled cold plate as in FIG. 26 fluidically coupled with the opposed, liquid-cooled condenser blocks shown in FIG. 18.

FIG. 28 shows an isometric view of a representative multi-chip module embodied as a DDR5 DIMM.

FIG. 29 shows an isometric view of a liquid-cooled condenser block suitable for use in a hybrid single-phase and two-phase embodiment as in FIG. 18.

FIG. 30 shows another isometric view of the liquid-cooled condenser block shown in FIG. 29.

FIG. 31 shows the liquid-cooled condenser block from FIG. 29 with a cap removed to reveal an internal passageway through the condenser block.

FIG. 32 shows a cross-sectional view of the liquid-cooled condenser block taken along plane XXXII-XXXII in FIG. 31.

FIG. 33 shows an isometric view of a rendering of the sectioned block in FIG. 32.

### DETAILED DESCRIPTION

The following describes various principles related to hybrid cooling systems incorporating a liquid cooling circuit and one or more two-phase cooling components with particular embodiments being suitable for cooling multi-chip modules. For example, aspects of disclosed principles pertain to liquid-cooled condenser blocks that facilitate heat-transfer from passive, two-phase cold plates to a liquid coolant. As well, aspects of disclosed principles pertain to passive, two-phase cold plates that can be placed in thermal contact with a plurality of DRAM and other heat-generating components. Further, aspects of disclosed principles pertain to approaches for thermally coupling such passive, two-phase cold plates with such liquid-cooled condenser blocks. That said, descriptions herein of specific apparatus configurations and combinations of method acts are but particular examples of contemplated systems chosen as being convenient, illustrative examples of disclosed principles. One or more of the disclosed principles can be incorporated in various other systems to achieve any of a variety of corresponding system characteristics.

Thus, systems having attributes that are different from those specific examples discussed herein can embody one or more presently disclosed principles and can be used in applications not described herein in detail. Accordingly, such alternative embodiments also fall within the scope of this disclosure.

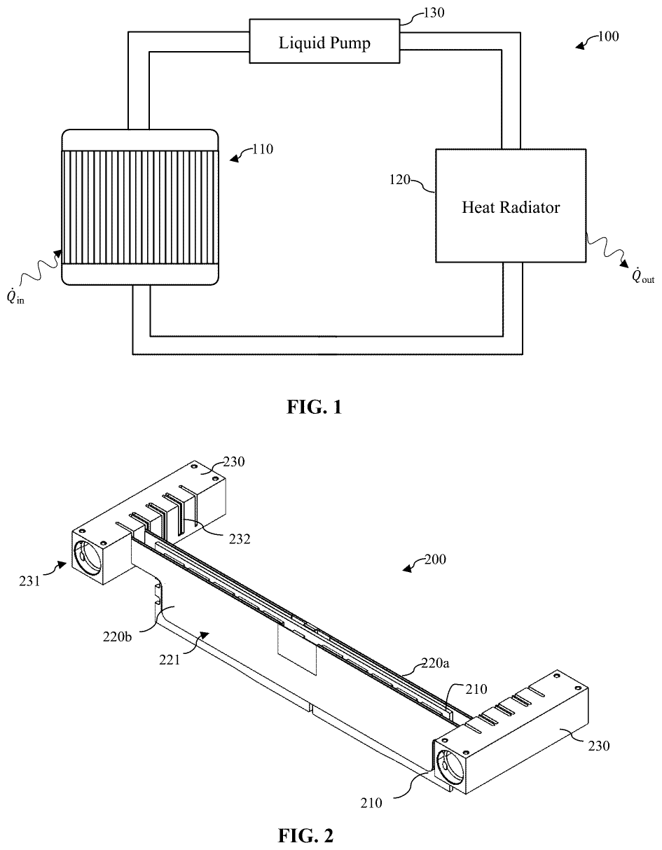

As noted above, FIG. 1 schematically illustrates a closed liquid-cooling loop 100. The liquid-cooling loop 100 includes a heat exchanger 110 that removes heat, \dot{Q}ᵢₙ, from a component (not shown) that generates heat while operating. However, the heat exchanger 110 need not be limited to cooling a single electronic component that dissipates heat while operating. For example, some electronic devices, e.g., servers (alone or installed in a rack, which itself may be installed in a data center), desktop computers, power electronics devices, etc., include a multi-chip module. And, some electronic devices include more than one such multi-chip module. Further, some multi-chip modules require rates of cooling beyond that which air cooling alone can achieve within some electronic devices. Accordingly, some electronic devices require augmented cooling for some or all components mounted to, for example, a multi-chip module.

Accordingly, the heat exchanger 110 shown in FIG. 1 can be configured to cool the heat-dissipating components of one or more multi-chip modules. For example, the heat exchanger 110 can conductively receive heat from the components and transfer it to a liquid coolant passing through the heat exchanger. As described above in connection with FIG. 1, the liquid coolant can flow from the heat exchanger 110 to a heat radiator 120, carrying the received heat to the radiator. As the heated coolant flows through the heat radiator, heat, \dot{Q}ₒᵤₜ, can be transferred to another cooling medium, cooling the liquid coolant. The cooled liquid coolant can again pass through the heat exchanger 110 to remove further heat dissipated by the heat-dissipating components of the one or more multi-chip modules (and/or other components). Additionally, one or more pumps 130 can urge the liquid coolant throughout the components of the cooling loop 100.

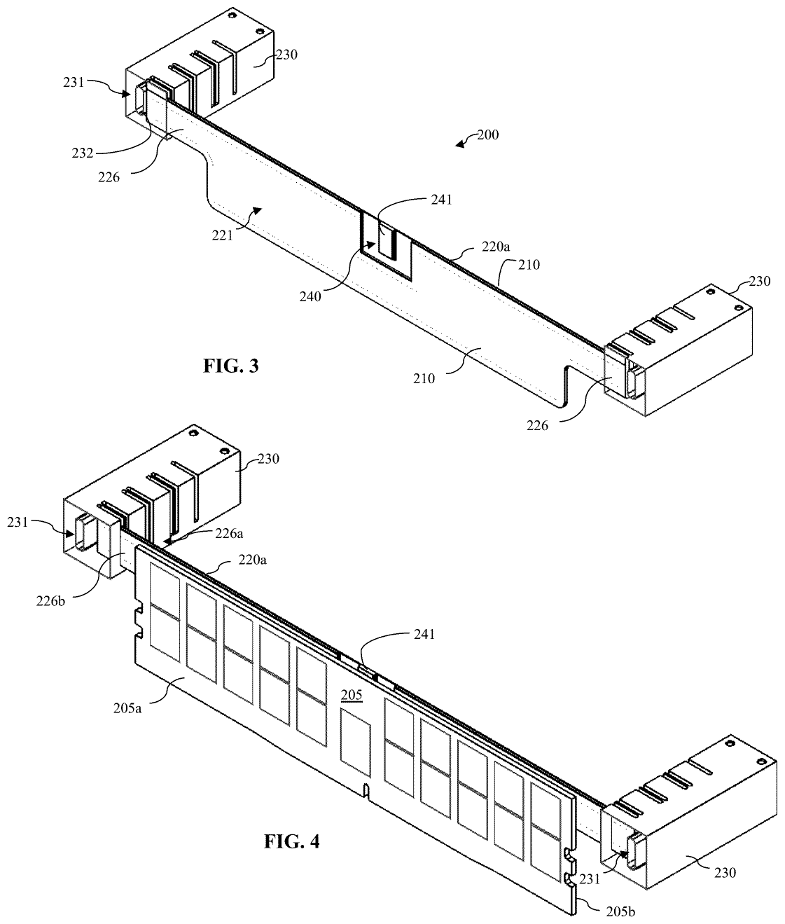

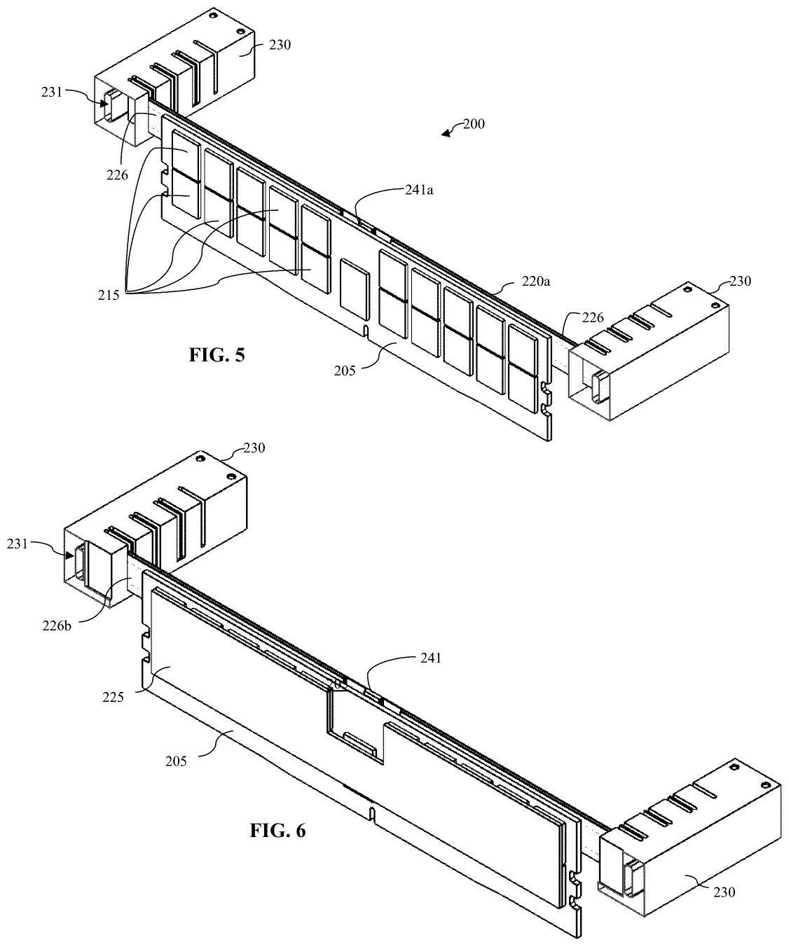

Referring now to FIG. 2, an embodiment of a heat exchanger 110 will be described in context of a hybrid cooling apparatus 200 for cooling a multi-chip module 210 (also see FIG. 5). In FIGS. 2 and 5, the multi-chip module 210 includes a circuit-board substrate 205 (see FIG. 4) having opposed major faces 205a, 205b. Atypical embodiment of the multi-chip module has a plurality of heat-generating components 215 (see FIG. 5) mounted to one or both major faces 205a, 205b of the substrate 205. In the embodiment shown in FIG. 2, a respective plurality of heat-generating components is mounted to each of the opposed major faces 205a, 205b. A pair of opposed, passive, two-phase cold plates 220a, 220b (see FIG. 2 and FIG. 3) overlies the multi-chip module 210, with a first plurality of heat-generating components 215 (e.g., DRAMs) thermally coupled with a first one of the passive, two-phase cold plates 220a and a second plurality of heat-generating components 215 (e.g., DRAMs) thermally coupled with the other one of the passive, two-phase cold plates 220b. Although passive, two-phase cold plates are described herein for purposes of succinctness and convenience, the use of passive cold plates in combination with liquid-cooling systems is not so limited. Rather, all embodiments of passive, two-phase cold plates described herein can be a thermally conductive plate (or sheet), in lieu of or in addition to a passive, two-phase cold plate, which typically refers to a vapor chamber, a heat pipe, or a thermosyphon, with or without additional features. Such a thermally conductive plate (or sheet) can be a solid, thermally conductive metal or it can be made of a composite having a binder or carrier and filler material. In other embodiments, such a thermally conductive plate can include or be made from, for example, ceramic or other non-metallic materials, e.g., a carbon nanotube. Further, disclosed conductive plates need not be homogenous or otherwise formed of a continuous, monolithic material but instead can be made from or incorporate a plurality of features made from one or more materials combined together in a suitable fashion to provide a thermally conductive path from one or more heat-generating components to a relatively cooler region, e.g., a liquid-cooling loop or a component thereof (e.g., a condenser block).

A passive, two-phase cold plate can be embodied as a vapor-chamber cold plate, a heat-pipe (e.g., a flattened heat pipe) cold plate, or a combination thereof.

A thermal-interface material 225 (see FIG. 6) can be positioned between the second plurality of heat-generating components and the second one of the passive, two-phase cold plates 220b. In an embodiment, the thermal-interface material 225 is a so-called thermal-gap pad having a finite thickness sufficient to span a gap between the heat-generating components 215 (FIG. 5) and the overlying passive, two-phase cold plate (e.g., cold plate 220b), while being sufficiently compliant to absorb variations in gap dimension between the components and the cold plate. Embodiments of the thermal-interface material 225 can include a thermal gap pad, a thermal gel, a thermal putty, a thermal grease, a thermal epoxy, or a combination thereof. Such a thermal-interface material 225 can be any thermally conductive material (e.g., a less-thermally conductive matrix material combined with a thermally conductive fill material dispersed throughout the matrix, which provides a higher bulk thermal conductivity for the composite material than for the matrix material alone) applied within a gap (of whatever dimension) between the cold plates 220a, 220b and the heat-generating components.

For example, when a thermal epoxy is used to enhance conductive heat transfer between the components 215 and the passive, two-phase cold plate 220a or 220b, a clip or other retainer that compresses the cold plate against the heat-generating components can be eliminated. In some embodiments with non-adhesive thermal-interface materials, such a clip can also be eliminated, as the liquid-cooled condenser block can cause the cold plates 220a, 220b to urge toward each other, e.g., by virtue of slots in the block being placed sufficiently close together that the cold plates urge toward each other, compressing the multi-chip module between the cold plates.

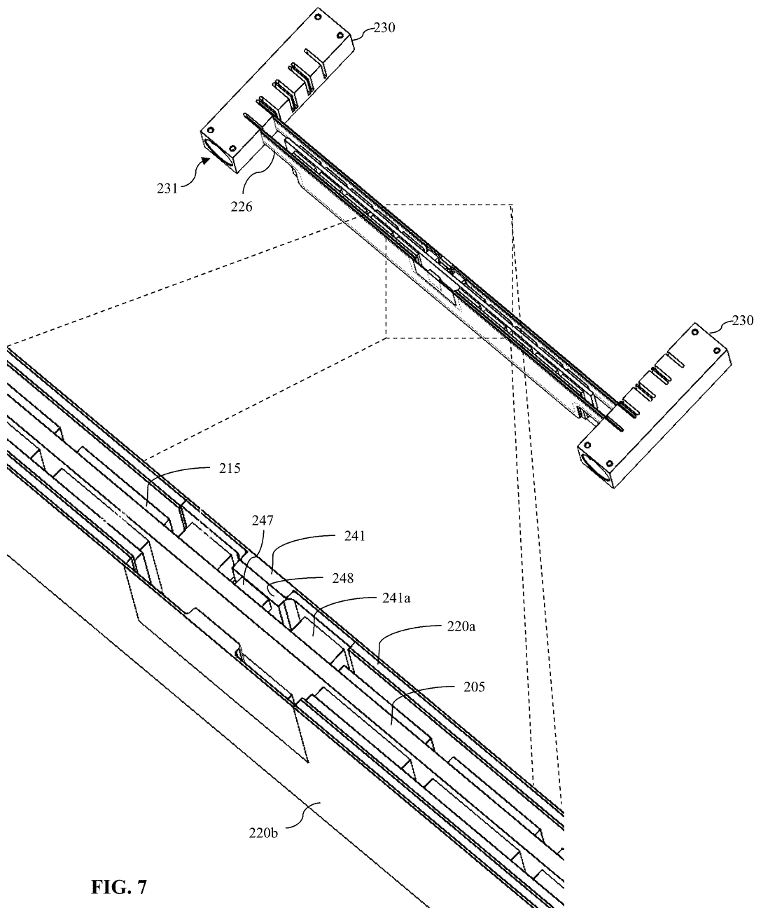

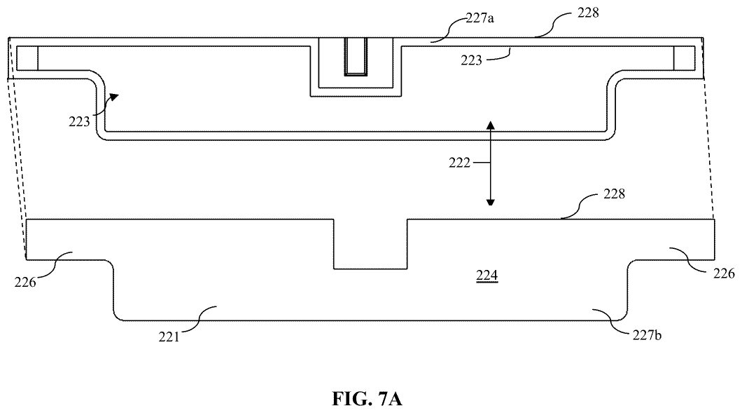

The enlarged region in FIG. 7 depicts an embodiment of such a gap pad (GP) spanning a gap between a heat-generating component (e.g., an EEPROM (SPD)) and a region of a passive, two-phase cold plate. Further, such a thermal-gap pad typically includes a thermally conductive filler to facilitate conductive heat-transfer across the gap from the heat-generating components 215 and the cold plate 220b.

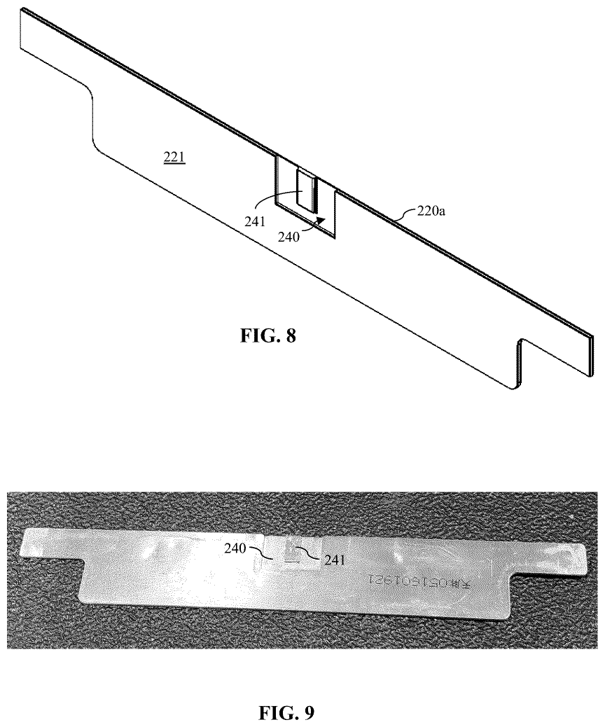

As shown among FIGS. 2 through 6, a passive, two-phase cold plate 220a, 220b can define a body portion 221 dimensioned and contoured to overlie and thermally contact one or more heat-generating components 215. Referring now to the exploded view in FIG. 7A, the body portion 221 can define an enclosed, interior chamber 222 having a porous wick 223 (cross-hatched region) therein, as well as a working fluid (not shown), e.g., in a saturated state comprising a mixture of liquid-phase and gas-phase. A boundary wall 224 of the enclosed chamber 222 defines an external major surface of the cold plate, which can be placed into thermal contact with a heat source 215 to cool the heat source. Further, the enclosed chamber 222 can define a trough-shaped region 240 (FIGS. 3 and 8) recessed from a periphery of the cold plate. A metal plate (or other conductive plate) can span across the trough-shaped region 240 and a thermal boss 241 can be positioned within the recess defined by the trough-shaped region. For example, the thermal boss can be a block of material welded, brazed, or soldered to the plate, or the thermal boss 241 can be defined by an additive or a subtractive machining or other manufacturing process. The thermal boss 241 provides the cold plate with a conductive heat-transfer region suitable for being placed into thermal contact with a heat-generating component 241a (e.g., a DRAM, an EEPROM, power-electronics devices (e.g., voltage regulators)) that has a stand-off height from the circuit-board substrate 205 (FIG. 4) different from a stand-off height of another heat-generating component 215, e.g., a DRAM. The enlarged portion of FIG. 7 depicts such an embodiment of a thermal boss 241 being thermally coupled with a heat-generating component 247 (analogous to heat-generating components 241a). In the enlarged portion of FIG. 7, a thermal-interface material 248 (analogous to thermal-interface material 225 in FIG. 6 or thermal-interface material 234 in FIG. 15, or both) and is positioned between the thermal boss 241 and the heat-generating component 247, thermally coupling the heat-generating component 247 with the thermal boss 241.

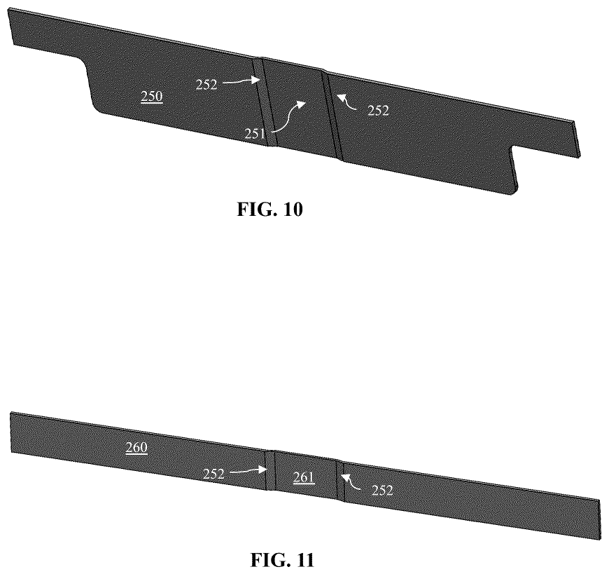

Other contoured body portions 221 also are possible to accommodate components of different stand-off heights. For example, referring to FIGS. 10 and 11, a passive, two-phase cold plate 250, 260 can define an out-of-plane region 251, 261 set back from a generally planar major portion of the body portion 221. The transition regions 252 can have a radiused contour to prevent locally collapsed regions of the interior chamber 222 that would tend to choke (i.e., inhibit) a flow of saturated coolant within the passive, two-phase.

Referring again to FIGS. 2 through 9, as heat transfers to a region of the cold plate through the external major surface, the liquid-phase of the working fluid adjacent the heated region of the cold plate can absorb the heat and evaporate. Evaporation of the liquid-phase introduces a pressure gradient within interior chamber 222 (FIG. 7A), urging the working fluid to move and to carry absorbed energy (as latent heat) with it. As gas-phase working fluid encounters a relatively cooler region of the cold plate (e.g., an end region 226 (FIG. 3)), the gas-phase can reject heat to the cooler region, causing the gas-phase to condense adjacent the relatively cooler region of the cold plate (e.g., cold plate 220a). Liquid-phase working fluid that encounters the porous wick 223 can migrate, e.g., through capillary action, toward the heated region of the cold plate. On returning to the heated region of the cold plate, the liquid-phase can absorb further heat, evaporate and carry the absorbed energy to the cooler region, circulating the working fluid within the interior chamber.

As depicted in FIG. 7A, the enclosed, interior chamber 222 can be defined, for example, between a first shell member 227a and a second shell member 227b sealably affixed with each other around a perimeter region. One or both of the first shell member and the second shell member can define the boundary wall 224, which in turn can define an external major surface and a corresponding outer periphery 228. The outer periphery 228 of the first shell member 227a can be sealably affixed with a corresponding outer periphery 228 of the second shell member 228a, sealing the enclosed chamber and capturing the working fluid therein. For example, a brazed, soldered or welded joint can sealably affix the respective peripheries 228 together

A porous wick 223 can be positioned within the enclosed interior chamber. In some embodiments, the wick and one or both shell members 227a, 227b are thermally coupled, e.g., conductively coupled, with each other. As but one example, a sintered metallic powder or other thermally conductive wick can be brazed to or otherwise placed in thermal contact with a region of one or both of the shell members adjacent an intended heat-receiving region (e.g., boundary wall 224) of the respective shell, as to direct condensed liquid coolant via capillary action toward and into the heated region of the interior chamber 222. The wick 223, however formed, can extend from the heated region (e.g., adjacent the wall 224) to a cooled region (e.g., an end region 226) of the cold plate where the evaporated coolant can condense as it rejects heat to the cooled region of the cold plate. With such a wick, the condensed coolant can be efficiently conveyed, via capillary action, through the wick from the cooled region to the heated region. In an embodiment, a portion of the interior chamber 222 can be generally devoid of the porous wick structure, as to provide unobstructed passage of gas-phase coolant from the heated region to the cooled region of the cold plate, generally driven via pressure gradients arising from conservation of mass principles as the coolant evaporates and condenses as described above.

In an embodiment, the heat-generating component 215 can be one or more DRAM or other components (e.g., an SPD) mounted to a memory or other circuit-board substrate. The relatively cooler region of the cold plate (e.g., the end region 226) can be thermally coupled with a cooled condenser block 230. Referring to FIG. 2, such a cooled condenser block can facilitate heat transfer from the cold plate 220a, 220b (or a region thereof, e.g., the relatively cooler end region 226) to a coolant circulating through a closed loop, a segment 231 of which passes through the cooled condenser block 230. The coolant, in turn, can reject heat absorbed from the condenser block to another medium, generally as described above in relation to the heat radiator shown in FIG. 1.

For example, referring still to FIGS. 2 through 6 and 7A, a passive, two-phase cold plate 220a, 220b can define opposed end regions 226 extending longitudinally outward from the body portion 221. In some embodiments, the opposed end regions 226 define internal condenser regions where a vapor-phase of the working fluid internal to the passive, two-phase cold plate condenses to the liquid-phase. In such embodiments, a portion of the working fluid within the passive, two-phase cold plate condenses within a volume defined by an outer surface of the condenser block. Further, in such embodiments, the conductive heat-transfer path from the region where the working fluid condenses to the condenser block is short, enhancing heat-transfer compared to embodiments that provide a relatively longer heat-transfer path from the region where the working fluid condenses to the condenser block.

Nevertheless, in other embodiments, the opposed end regions 226 are solid or substantially solid (e.g., a collapsed region of a heat-pipe or vapor-chamber that inhibits passive circulation of the internal working fluid). In such embodiments, the walls of the passive, two-phase cold-plate in the vicinity of the end-regions 226 conduct heat absorbed from the working fluid (as it condenses adjacent the end-region) to the condenser block. Accordingly, in such embodiments, the conductive heat-transfer path from the region where the working fluid condenses to the condenser block can be longer than when the working fluid condenses within a volume defined by the outer surfaces of the condenser block 230. Nevertheless, condensing the working fluid external to the condenser block can provide a relatively larger surface area for condensation to occur and thus, in some embodiments, can provide an improved overall rate of cooling to the multi-chip module than when some or all of the condensation occurs within the volume defined by the condenser block.

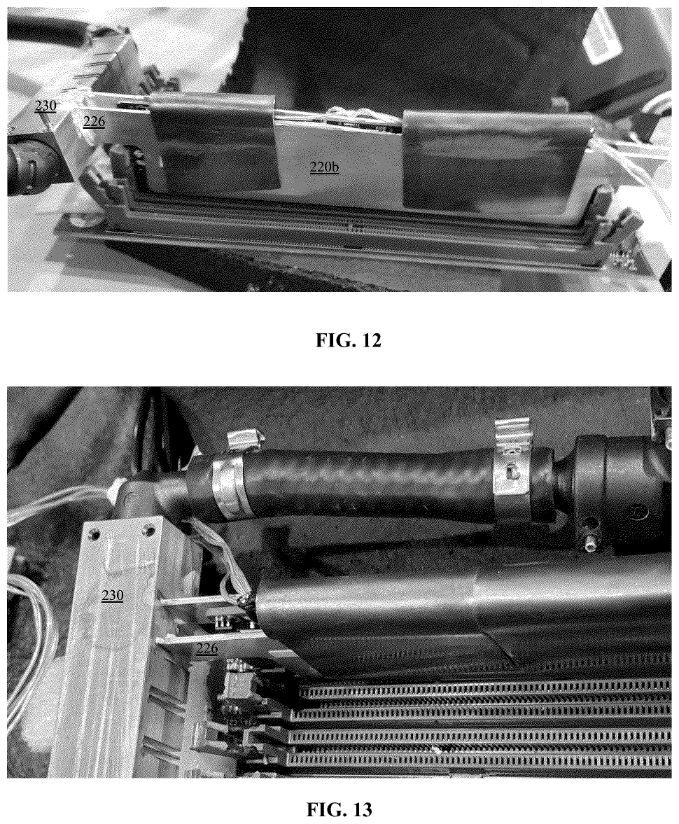

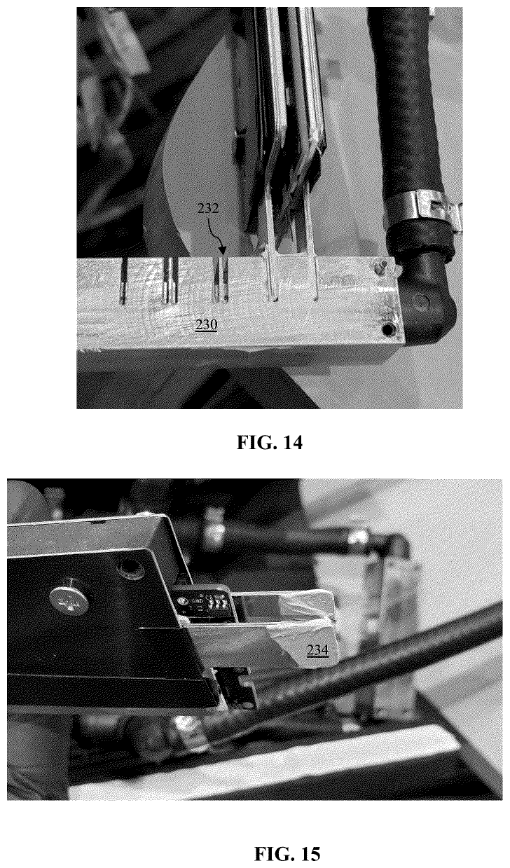

Referring still to FIG. 3, one or both of the opposed end regions 226 can be fit, e.g., press-fit, within a slot 232 defined by a corresponding condenser block 230. The close fit of the laterally outward faces 226a, 226b (FIG. 4) of each end region 226 within the inwardly facing walls defined by the recessed slots 232 facilitates conductive heat transfer between the end regions 226 and the body 233 of the condenser block 230. Moreover, as shown among the photographs in FIGS. 12 through 15, thermal contact between the end regions 226 and the body 233 of the condenser block 230 can optionally be improved by adding a thermal-interface material 234 (FIG. 15) between the surfaces of the end regions 226 and the inner walls of the slot 232 (FIG. 14). Not all embodiments incorporate a thermal interface material 234 at an interface between the condenser block 230 and the surfaces of the end regions 226.

For example, referring still to FIGS. 2 through 6, liquid (e.g., a sub-cooled liquid) coolant can pass through a passage 231 of each cooled condenser block 230, absorbing heat rejected from the end regions 226 of the cold plate 220a, 220b. In another embodiment, a cooled refrigerant (e.g., from a two-phase refrigeration cycle) passes through a passage 231 of each cooled condenser block 230 and absorbs heat rejected from the cold plate. With either of the immediately two preceding embodiments, the coolant (or refrigerant) can circulate through a cooling loop (e.g., the cooling loop 100 in FIG. 1), carrying with it heat absorbed from the cold plate and condenser block (e.g., similar to the heat exchanger 110), and can reject the heat to another medium (e.g., another intermediate working fluid or an ultimate heat sink, such as, for example, the atmosphere), as with the heat radiator 120.

Although the embodiment depicted among FIGS. 2 through 9 includes opposed condenser blocks 230, each being configured to receive one of the opposed end regions 226, other embodiments provide just one such condenser block and thus provide cooling to a selected one of the end-regions 226 of the passive, two-phase cold plate (e.g., vapor-chamber cold plate). Additionally, or alternatively, some embodiments provide thermal contact between the block and one major surface of the end-region 226, e.g., instead of thermal contact between the opposed major surfaces of the end-region 226 as shown among the drawings. Such thermal contact can be generally as depicted in FIG. 3, with a gap existing between the major surface of the end-region 226 visible in FIG. 3 and a corresponding opposed region of the condenser block 230.

In an embodiment, a cooled condenser block 230 comprises a thermally conductive body 233 defining an internal passageway 231 through which a liquid coolant flows to remove heat from the condenser block, cooling it. The condenser block 230, in turn, can facilitate heat transfer from one or more cold plates 220a, 220b, e.g., one or more vapor-chamber cold plates, to the liquid coolant passing through the condenser block. For example, the condenser block 230 can define one or more recessed slots 232 defining an open face (see FIG. 14) and a plurality of interior surfaces recessed from the open face. A portion of a cold plate, e.g., an end-region 226 of a cold plate 220a, 220b, can be inserted (e.g., press-fit) into one such slot. The slot can be so sized relative to the end-region 226 as to cause opposed major surfaces 226a, 226b of the end-region to urge outwardly against inwardly facing interior surfaces of the slot 232. Such urging between the end-region of the cold plate and the interior surfaces of the slot can provide thermal contact, and thus a conductive heat-transfer path, between the end region 226 and the condenser block 230, and thus between the cold plate 220a, 220b and the liquid coolant within the passage 231 through the condenser block 230. Such thermal contact can be enhanced by incorporating a thermal-interface material 234 (e.g., a so-called “thermal grease,” which often can be described as a slurry of a thermally conductive and electrically inert ceramic powder, such as, for example, aluminum oxide, suspended in a mineral oil or other oil, or any of a variety of other thermal-interface materials described herein or otherwise known in the art).

In an embodiment, a clasp, cam, or other mechanical device can be configured to compressively urge an end-region of the cold plate against one or more of the interior faces of the slot. Moreover, some embodiments leave a gap between another interior face of the slot and the end-region of the cold plate. In some embodiments, passive, two-phase cold plates are urge against the heat-generating components by virtue of being bonded with them (e.g., with a thermally conductive epoxy or other adhesive). Additionally, or alternatively, the cold plate urges against the heat-generating components on one or both sides of a multi-chip module under mechanical loading imposed by the condenser block 230. For example, the slots 232 (in the condenser block) corresponding to each passive, two-phase cold plate (or more particularly, the end-region thereof) can be laterally spaced more closely to each other than the cold-plates are when at-rest and unloaded on a multi-chip module. On insertion of the module in an edge or other connector, the slots 232 in the condenser block 230 can matingly receive the end-regions 226 of the cold plate 220a, 220b. Because the slots 232 are more closely positioned to each other than the cold plates in their at-rest position in relation to the multi-chip module, the condenser block can urge the cold plates toward each other, compressing the gap between the cold plates and the heat-generating components and improving thermal contact therebetween. In some embodiments, such compression can lead to a bow in the cold plate and interfere with thermal contact between the cold plate and one or more heat-generating components. Thus, in some, but not all, embodiments, such compression applied by the condenser block may be desirable, and in other embodiments, it may be undesirable. In some embodiments, the one or more interior walls of the slot 232 is angled such that a cross-sectional dimension of the slot tapers from a relatively larger gap adjacent an open face of the slot to a relatively narrower gap at an interior position within the recessed slot 232. Such a taper can better facilitate insertion of the cold-plate-and-module-assembly into an edge connector and the condenser block compared to embodiments in which the recessed slot 232 has a uniform gap between the inner walls.

In some embodiments, the interior chamber 222 defined by the cold plate extends into the end-region 226 of the cold plate such that a portion of the cooled region of the interior chamber 222 extends inwardly of the condenser block 230 (e.g., within the slot 232). In other embodiments, the end region 226 of the cold plate comprises a stud or plate of thermally conductive material extending longitudinally of the interior chamber, such that the interior chamber does not extend into any portion of the condenser block. In either embodiment, the liquid coolant passing through the condenser block can absorb heat from the condenser block, which in turn absorbs heat from the cold plate.

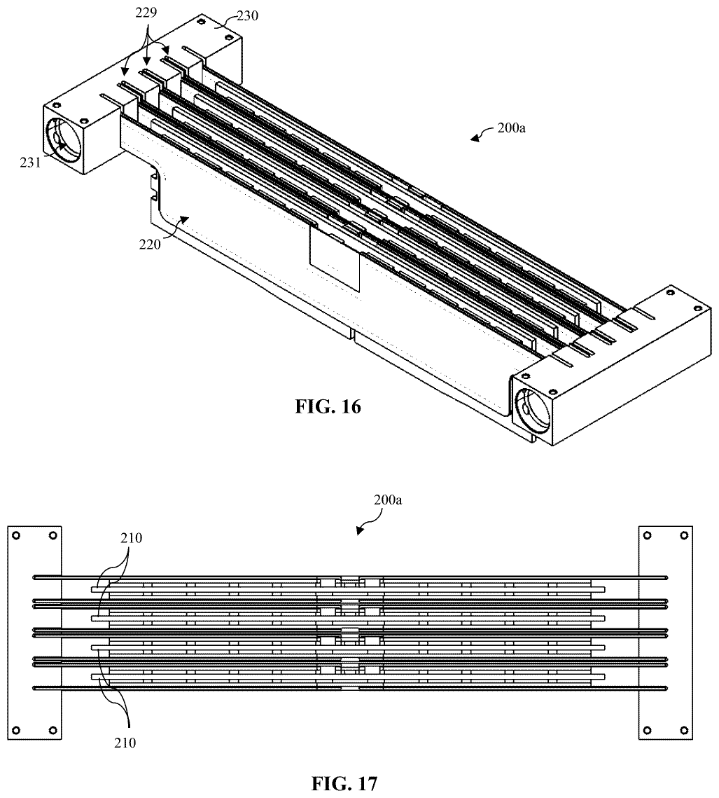

Among FIGS. 2 through 9, each hybrid cooler (e.g., the two-phase vapor-chamber component being thermally coupled with a liquid-cooled condenser block) is shown with two vapor-chamber cold plates mounted to a single DIMM. Nevertheless, disclosed hybrid coolers are not limited to two vapor-chamber cold plates per DIMM, let alone limited to the cold plate(s) of just one DIM being thermally coupled with the cooled condenser block. Rather, as the photographed working embodiments shown among FIGS. 12 through 15 indicate, disclosed condenser blocks can thermally couple with, and cool, a plurality of DIMMs, each having one or more cold plates thermally coupled with the heat-generating components thereof as described above. For example, FIGS. 16 and 17 show an embodiment configured to cool a plurality of multi-chip modules (e.g., DDR5 DIMMs).

In such embodiments, each vapor-chamber cold plate has a sealed enclosure that defines an external major surface being in thermal contact with a plurality of heat-generating components. Further, each respective sealed enclosure contains a thermodynamically saturated coolant that circulates passively within the sealed enclosure to distribute heat from the heat-generating components throughout the enclosure. Each vapor-chamber cold plate also has an end region defining a major surface that is in thermal contact with the liquid-cooled condenser block, providing a heat-transfer path from the plurality of heat-generating components to a liquid coolant passing through the liquid-cooled condenser block.

Referring still to FIGS. 16 and 17, the cooler 200a includes a pair of passive, two-phase cold plates 220 positioned opposite each other relative to each multi-chip module 210 to be cooled. In FIGS. 16 and 17, each of the passive, two-phase cold plates 220 has a condenser region 226 thermally coupled within a slot 232 defined by the condenser blocks 230, as described above and shown in, for example, FIG. 3. The embodiment in FIG. 16 includes four (4) such multi-chip modules to be cooled and eight (8) passive, two-phase cold plates 220, i.e., two passive, two-phase cold plates per multi-chip module. Other embodiments provide more or fewer multi-chip modules cooled using such techniques as are described herein. Still other embodiments can use a single passive, two-phase cold plate positioned between adjacent multi-chip modules, rather than two passive, two-phase cold plates positioned immediately adjacent each other as with the embodiment shown in FIGS. 16 and 17. For example, each adjacent pair 229 (FIG. 16) of passive, two-phase cold plates 220 can be replaced with a single, e.g., thicker, passive two-phase cold plate (not shown). In such an embodiment, the individual slots 232 shown in FIGS. 16 and 17 corresponding to each adjacent pair 229 of passive, two-phase cold plates 220 can be replaced with a single, larger slot (not shown) sized to accommodate an end region (analogous to the end region 226 of the cold plate 220) of the single, e.g., thicker, passive two-phase cold plate.

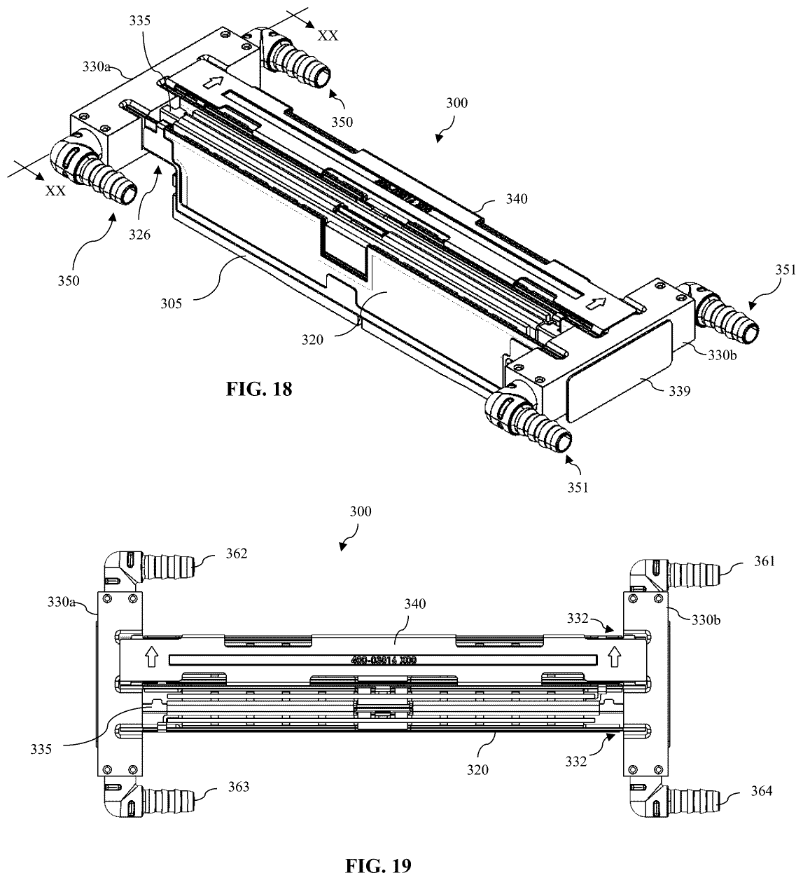

Referring now to FIG. 18, another embodiment of a hybrid cooler 300 is described. The hybrid cooler 300 provides a centrally positioned liquid-cooled cold plate 335 between each pair of multi-chip modules 305. Each of the outer sides of the modules 305 (relative to the inner sides of the modules 305, which are in thermal contact with the liquid-cooled cold plate 335) is in thermal contact with one of a pair of passive, two-phase cold plates 320. The passive, two-phase cold plates 320 can be configured as described above in connection with the passive, two-phase cold plates 220. Further, the passive, two-phase cold plates 320 can have opposed condenser regions 326 placed in thermal contact with the liquid-cooled condenser blocks 330, as in the embodiments described above. In addition, the liquid-cooled cold plate 335 can be fluidically coupled with an internal passageway 336 of the liquid-cooled condenser blocks 330.

In the embodiment depicted in FIG. 18, cool coolant can enter inlet regions 350 of the condenser block 330a from a coolant loop, e.g., a coolant loop as described by way of reference to FIG. 1. The inlet regions 350 convey the cool coolant through the condenser block 330a, cooling the corresponding condenser regions 326 of the passive, two-phase cold plates 320 generally as described above. As well, the fluid coupling between the condenser block 330a and each liquid-cooled cold plate 335 conveys the liquid coolant from the condenser block 330a to an internal passageway defined by each liquid-cooled cold plate 335. For example, the condenser block 330a can define one or more conduit openings, e.g., a port 333 in a condenser block 330 as in FIG. 32, fluidically coupled with an internal passageway defined by each liquid-cooled cold plate 335, e.g., a port defined by an end region 334 of the liquid-cooled cold plate 335 that opens to an internal passageway through the liquid-cooled cold plate. As the coolant passes through the internal passageway of the liquid-cooled cold plate 335, the coolant absorbs additional heat (relative to the passive, two-phase cold plate 320) from the multi-chip modules 305 flanking the liquid-cooled cold plate 335. A similar fluid coupling between the condenser block 330b and each liquid-cooled cold plate 335 conveys the coolant heated thusly to the condenser block 330b, as indicated by arrows 366 (FIG. 21) which has an internal passageway 326 (FIG. 31) that conveys the coolant to the outlet regions 351. U.S. Pat. No. 11,924,996, issued Mar. 5, 2024, the contents of which are hereby incorporated in their entirety as completely as if reproduced herein in full, for all purposes, disclosed liquid-cooled cold plates that are compatible with and suitable for embodiments of the liquid cooled cold plates 335 shown in FIG. 18.

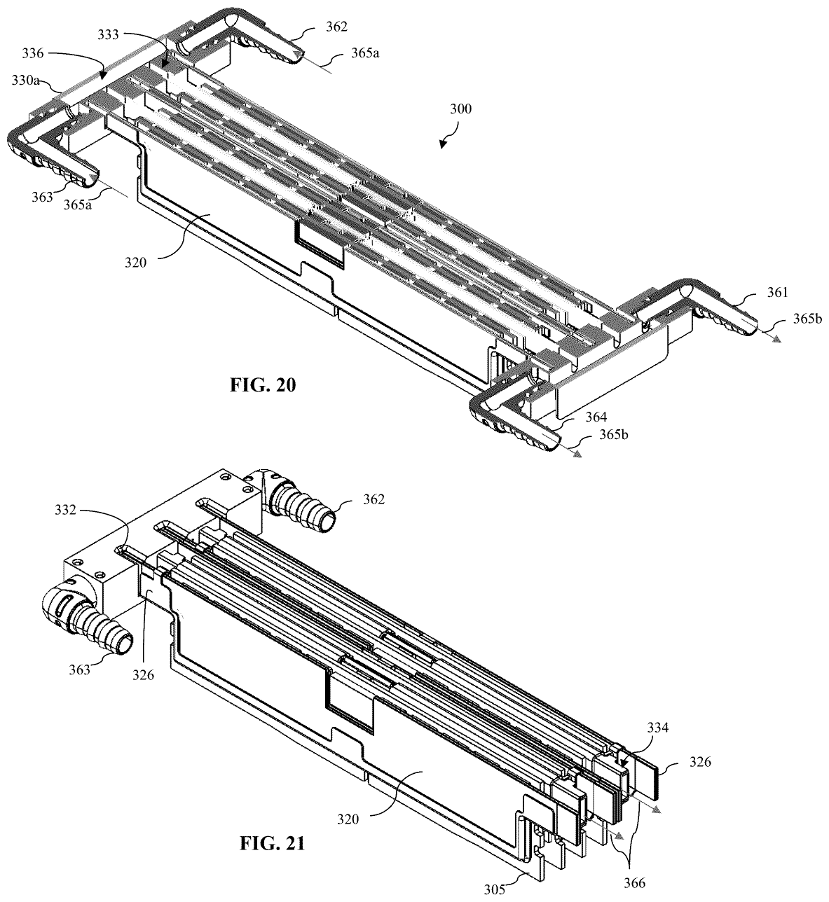

Referring now to FIG. 20, flow paths through the hybrid cooler 300 will be described. As noted above, cool coolant can enter the fluid couplers 362, 362 and heated coolant can exhaust from the hybrid cooler through the fluid couplers 361, 364, as indicated by the arrows 365a, 365b. Nevertheless, other flow arrangements through the hybrid cooler 300 are possible and even desirable in some systems. For example, cool coolant can enter the coupler 363 and the coupler 362 can be capped off or otherwise configured to prevent or inhibit fluid to flow therethrough. In such an embodiment, coolant will flow through the hybrid cooler and exhaust from the couplers 361, 364. In another embodiment, cool coolant can enter one or both couplers 362, 363 and one of the couplers 364, 365 can be capped off or otherwise configured to prevent or inhibit fluid to flow therethrough. In such an embodiment, coolant will flow through the hybrid cooler 300 and exhaust from the coupler 364, 365 that remains uncapped. Also, flow through the hybrid cooler 300 can be reversed, e.g., such that cool coolant enters the hybrid cooler 300 through one or both of the couplers 361, 364 and exhausts through one or both of the couplers 362, 363.

Fluid couplers 361, 362, 363, 364 can be embodied in as any suitable fluid coupler. For example, suitable couplers have been disclosed in U.S. patent application Ser. No. 17/689,879, filed Mar. 8, 2022, the contents of which are hereby incorporated by reference in its entirety as completely as if set forth herein in full, for all purposes. Other suitable fluid couplers have been disclosed in U.S. Patent Application No. 63/666,642, filed Jul. 1, 2024, the contents of which are hereby incorporated by reference in its entirety as completely as if set forth herein in full, for all purposes. As but one example, a stud of a fluid coupler can be inserted into a corresponding recessed region 331 defined by a condenser block and secured in a manner as disclosed in the '879 application or the '642 application. A barbed or other region of the fluid couplers 361, 362, 363, 364 can be coupled with a conduit, providing means for coupling the hybrid cooler 300 with a cooling loop, e.g., as disclosed and described in connection with FIG. 1.

Referring now to FIG. 21, further aspects of a hybrid cooler, e.g., hybrid cooler 300, are described. With the condenser block 330b removed as in FIG. 21, respective end regions of the passive, two-phase cold plates 320 and the liquid-cooled cold plates 335 are shown. As FIG. 21 shows, the end regions 326 of the passive, two-phase cold plates 320 are closed and define outer surfaces suitable for making thermal contact with the recessed slots 332 of the condenser block 330b. As explained above, a thermal grease, a thermal epoxy, or other suitable thermal interface material can be used to improve thermal contact between the end regions and the condenser block relative to a bare interface.

As FIG. 21 also shows, each end region 334 of the liquid-cooled cold plates 335 defines an opening 334a to an internal passageway within the respective cold plate. When the end regions 334 of the liquid-cooled cold plates 335 are inserted into the corresponding openings 333 (FIG. 30) defined by the condenser block 330, the internal passageway of the liquid-cooled cold plate 335 is fluidically coupled with the internal passageway 336 (FIG. 30) of the condenser block. The cross-sectional view in FIG. 20 shows the conductive thermal coupling between the passive, two-phase cold plates 320 and the condenser block 330, as well as the fluid coupling between the liquid-cooled cold plate 335 and internal passageway 336 of the condenser block 330.

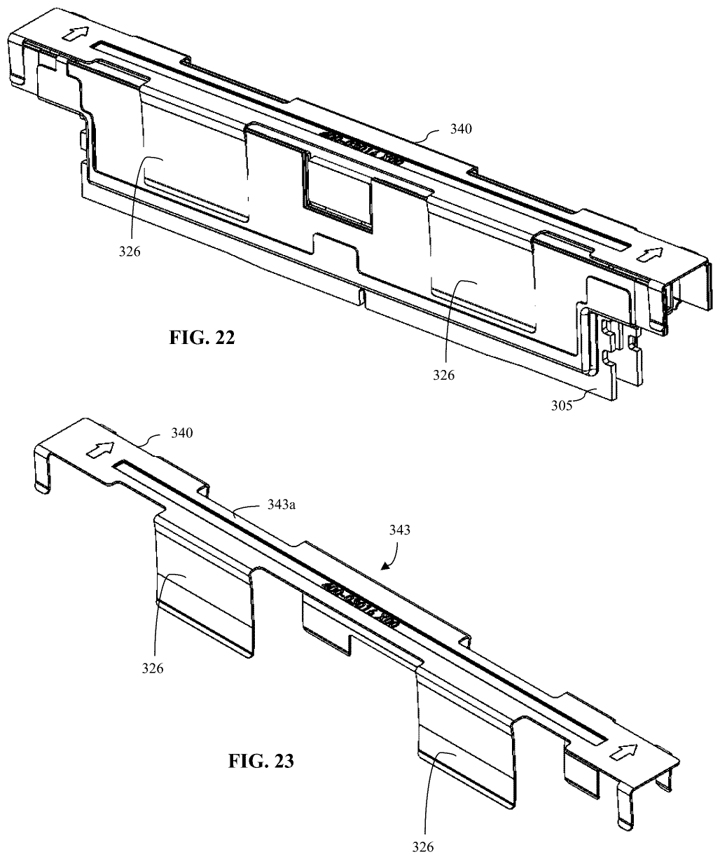

FIG. 22 shows a clip, or a bracket, 340 can be positioned overtop an assembly of passive, two-phase cold plates 320, multi-chip modules, and a liquid-cooled cold plate 335. FIG. 22 shows the clip 340 as installed and FIG. 23 shows the clip 340 removed, standing alone. The clip 340 has opposed fingers, bars or arms 326, 343 that extend downwardly from a spine 343a. The opposed arms 326, 343 can compress a laminated assembly of passive, two-phase cold plates 320, multi-chip modules, and a liquid-cooled cold plate 335 (FIG. 24), enhancing thermal contact between opposed major surfaces of passive, two-phase cold plates 320, multi-chip modules 305, and the liquid-cooled cold plate 335. Embodiments of similar clips are disclosed in U.S. patent application Ser. No. 17/201,394, filed Mar. 15, 2021, the contents of which are hereby incorporated by reference in its entirety as completely as if set forth herein in full, for all purposes.

FIG. 24 shows the assembly with the clip removed. As FIG. 24 shows, a liquid-cooled cold plate 335 can be positioned between and in thermal contact with a pair of multi-chip modules 305 (e.g., DIMMs). For example, opposed major surfaces of the cold plate 335 can be placed in thermal contact with the inwardly facing major surfaces of the multi-chip modules 305. As FIG. 24 shows further, a pair of passive, two-phase cold plates 320 can be positioned laterally outward of and in thermal contact with the outwardly facing major surfaces of the multi-chip modules 305. In FIG. 22, the clip 340 is positioned overtop just such an assembly, compressing the cold plates and multi-chip modules together, enhancing thermal contact at each interface between major surfaces. As noted elsewhere herein, thermal contact between components (e.g., between either type of cold plate 320, 335 and a heat-generating component, e.g., device 315, of the multi-chip module) can be further enhanced by placing a thermal-interface material between opposed surfaces of the components compared to an interface without such a thermal-interface material. In some embodiments, the thermal-interface material can be a gap-pad configured to fill a gap between components, the gap-pad being filled with a thermally conductive material to enhance conductive heat transfer across the gap-pad compared to a gap-pad without such a filler.

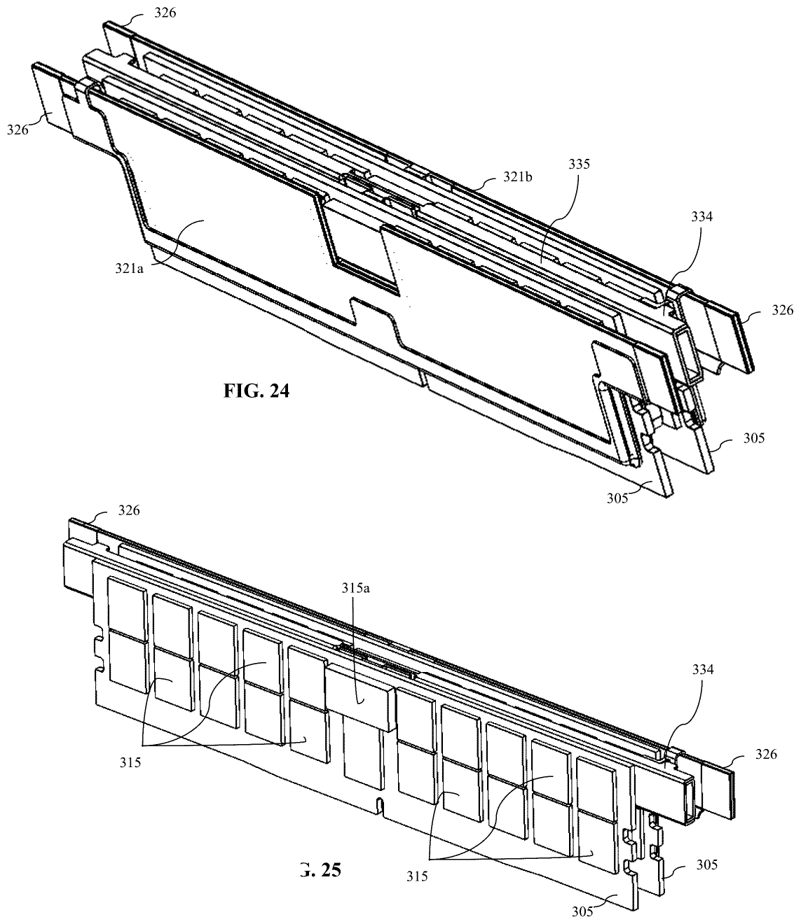

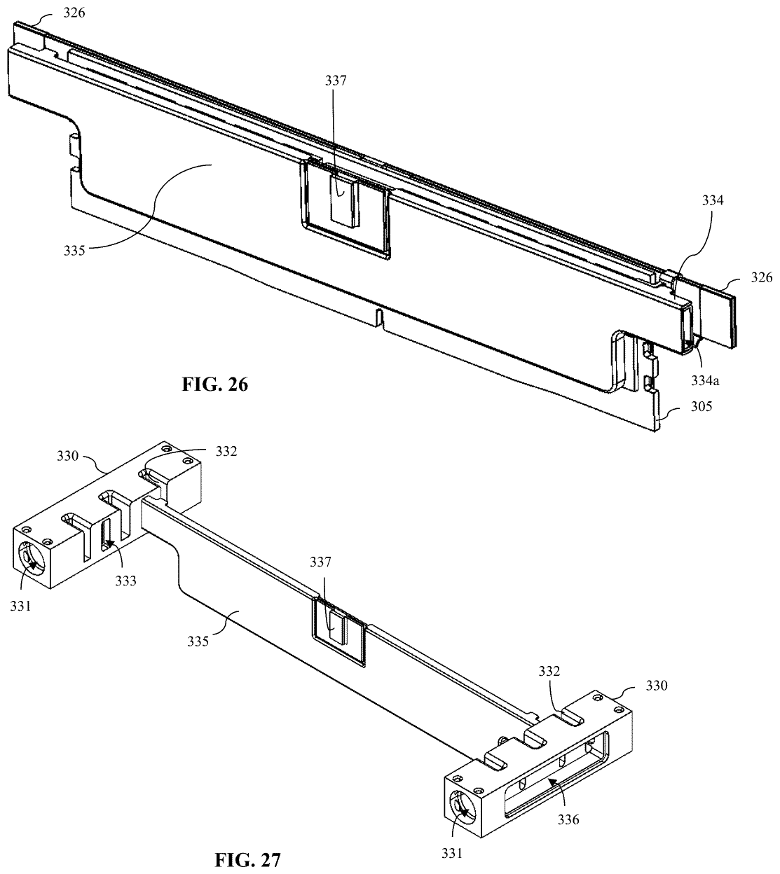

FIG. 25 shows the assembly depicted in FIG. 24 with the passive, two-phase cold plate 321a removed to reveal a major surface of one of the multi-chip modules 305 and the plurality of heat-generating components 315 (e.g., DRAMs) mounted thereto. As well, one or more other heat-generating components 315a, b (e.g., an on-DIMM memory controller, an EEPROM) is shown. In some embodiments, the passive, two-phase cold plates 320, the liquid cooled cold plate 335, or both, can have a boss, stud or other raised or recessed feature (e.g., 241 in FIG. 8, 252 in FIG. 10, 337 in FIG. 26) to facilitate a relatively thin bondline (e.g., which can provide enhanced thermal contact) between a major surface of the component 315a, 315b and a corresponding region of the major surface of the cold plate 320, 335. FIG. 26 shows the assembly in FIG. 25 with the one of the multi-chip modules 305 removed to reveal features of the liquid cooled cold plate 335.

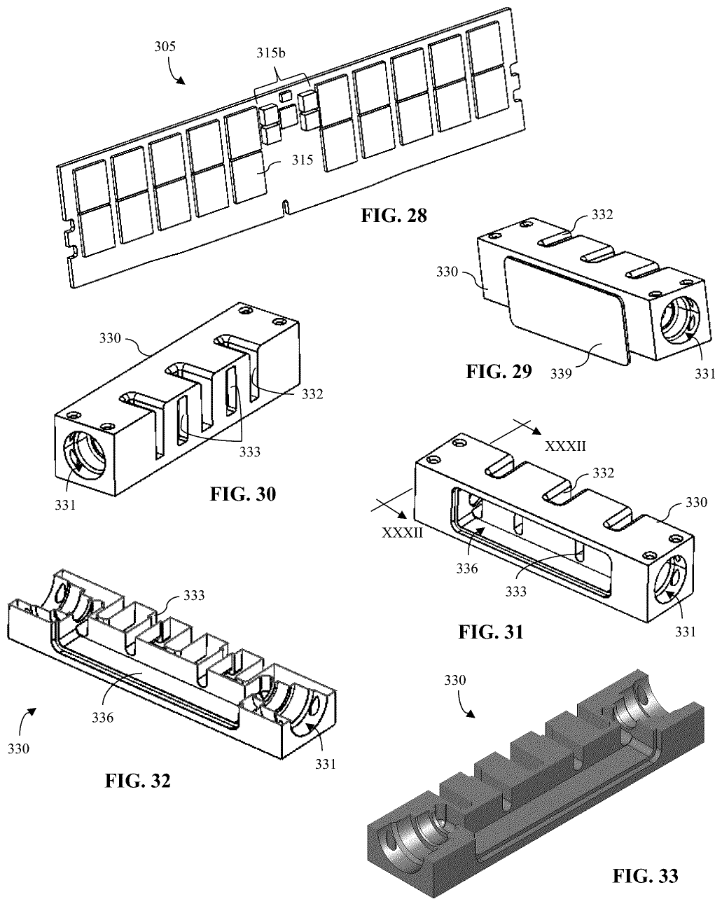

FIG. 27 shows the liquid-cooled cold plate 305 installed between the condenser blocks 330, with other system components, and the cap 339, removed to reveal additional detail of the hybrid assembly 300. FIG. 28 shows aspects of a representative multi-chip module 305 embodied as a DDR5 DIMM, and FIGS. 29 to 33 show features of a representative condenser block 300 suitable for use in a hybrid assembly 300.

Referring again to the schematic illustration in FIG. 1, any of the hybrid coolers as just described can be substituted for the heat exchanger 110. Alternatively, one or more hybrid coolers can be added to a cooling loop of the type depicted in FIG. 1. For example, the heat exchanger 110 shown in FIG. 1 may be placed in thermal contact with a processing component, and one or more hybrid coolers 200 as described herein can be fluidically coupled (in series or in parallel) with the heat exchanger 110. On reviewing this disclosure, a person of ordinary skill in the art will understand and appreciate the various modifications to fluid connections, pumping resources, and radiator configurations that such alternative arrangements could or would require in order to urge a sufficient flow of coolant through each heat exchanger/heat-exchanger assembly in a given cooling loop, as well as to reject absorbed heat from the coolant to another cooling medium.

Such cooling systems also can include a heat radiator configured to reject heat from the liquid coolant to another medium as the liquid coolant passes through the heat exchanger, generally as described above in connection with FIG. 1. Such cooling systems also include a pump configured to urge the liquid coolant throughout a closed loop, including the liquid-cooled condenser block and the heat exchanger.

A cooling system as just described can be installed in or on an electronic device to cool a multi-chip module alone or in combination with other heat-generating components (e.g., processing units). For example, as shown in FIG. 5, each multi-chip module 200 can have mounted thereto a plurality of active electronic components 215. Each active electronic component dissipates heat while operating. And, a typical memory module, for example, may have between four and forty, or more, active electronic components (e.g., DRAMs), as well as additional heat-dissipating components like power delivery devices, memory controllers, EEPROMs, etc. Moreover, a given electronic device may have an array of multi-chip modules installed, with each module being cooled by a cooling system as described above. For example, such an array of multi-chip modules may include one or more multi-chip modules, or one or more pairs of multi-chip modules.

The examples described above generally concern apparatus, methods, and related systems to cool one or more multi-chip modules, each having a plurality of active electronic components that generate heat while operating. Nonetheless, the previous description is provided to enable a person skilled in the art to make or use embodiments of the disclosed principles. Embodiments other than those described above in detail are contemplated based on the principles disclosed herein, together with any attendant changes in configurations of the respective apparatus or changes in order of method acts described herein, without departing from the spirit or scope of this disclosure. Various modifications to the examples described herein will be readily apparent to those skilled in the art.

For example, concepts described herein can be used to cool a plurality of other types of heat-generating components that are combined into a functional module (e.g., as with a DIMM or another multichip module, e.g., a processing unit that includes one or more processing cores or chips, together with one or more voltage regulating components (so-called “VR components”) or other modules that include, for example, a so-called intermediate bus converter (IBC). For example, a passive, two-phase cold plate can span across a plurality of such alternative components, even when the components have different heights from each other relative to the substrate to which they are mounted (e.g., by using concepts described herein, such as, for example, bending the cold plate). As above, the passive, two-phase cold plate can facilitate heat transfer from these alternative heat-generating components to a liquid cooling loop, e.g., in combination with an intermediate thermal interface structure similar in principle (even if not similar physical structure) to a thermal condenser block, e.g., block 230.

Directions and other relative references (e.g., up, down, top, bottom, left, right, rearward, forward, etc.) may be used to facilitate discussion of the drawings and principles herein, but are not intended to be limiting. For example, certain terms may be used such as “up,” “down,”, “upper,” “lower,” “horizontal,” “vertical,” “left,” “right,” and the like. Such terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface, and the object remains the same. As used herein, “and/or” means “and” or “or”, as well as “and” and “or.” Moreover, all patent and non-patent literature cited herein is hereby incorporated by reference in its entirety for all purposes.

And, those of ordinary skill in the art will appreciate that the exemplary embodiments disclosed herein can be adapted to various configurations and/or uses without departing from the disclosed principles. Applying the principles disclosed herein, it is possible to provide a wide variety of cooling devices for multi-chip modules, and related methods and systems to remove waste heat from such multi-chip modules. For example, the principles described above in connection with any particular example can be combined with the principles described in connection with another example described herein. Thus, all structural and functional equivalents to the features and method acts of the various embodiments described throughout the disclosure that are known or later come to be known to those of ordinary skill in the art are intended to be encompassed by the principles described and the features and acts claimed herein. Accordingly, neither the claims nor this detailed description shall be construed in a limiting sense, and following a review of this disclosure, those of ordinary skill in the art will appreciate the wide variety of cooling devices, and related methods and systems that can be devised using the various concepts described herein.

Moreover, nothing disclosed herein is intended to be dedicated to the public regardless of whether such disclosure is explicitly recited in the claims. No claim feature is to be construed under the provisions of 35 USC 112(f), unless the feature is expressly recited using the phrase “means for” or “step for”.

The appended claims are not intended to be limited to the embodiments shown and described herein, but are to be accorded the full scope consistent with the language of the claims, wherein reference to a feature in the singular, such as by use of the article “a” or “an” is not intended to mean “one and only one” unless specifically so stated, but rather “one or more”. Further, in view of the many possible embodiments to which the disclosed principles can be applied, we reserve the right to claim any and all combinations of features and technologies described herein as understood by a person of ordinary skill in the art, including the right to claim, for example, all that comes within the scope and spirit of the foregoing description, as well as the combinations recited, literally and equivalently, in any claims presented anytime throughout prosecution of this application or any application claiming benefit of or priority from this application, and more particularly but not exclusively to the claims appended hereto.

We currently claim:

1. A liquid cooling system, comprising:
a pair of opposed condenser blocks, each condenser block defining an internal fluid passage, the internal fluid passage having a first port and a second port;
a liquid-cooled cold plate having a first end and an opposed second end, opposed first and second major surfaces, and an internal passageway positioned between the opposed first and second major surfaces and extending from the first end to the opposed second end, wherein the first port of each condenser block is configured to fluidically couple with a coolant supply or a coolant collector, and wherein the second port of one of the condenser blocks fluidically couples with the first end of the liquid-cooled cold plate and the second port of the other of the condenser blocks so fluidically couples with the second end of the liquid-cooled cold plate that liquid-cooled cold plate extends from one in the pair of opposed condenser blocks to the other in the pair of opposed condenser blocks;
a passive cold plate having a first major surface positioned opposite and spaced apart from the first major surface of the liquid-cooled cold plate, defining a gap therebetween sized to receive a multi-chip module to be cooled by the liquid cooling system, the passive cold plate extending from a first end to an opposed second end, wherein one of the opposed condenser blocks defines a recessed slot configured to receive the first end of the passive cold plate and the other of the opposed condenser blocks defines a recessed slot configured to receive the second end of the passive cold plate.

2. The liquid cooling system according to claim 1, wherein the passive cold plate is a first passive cold plate, and the multi-chip module to be cooled by the liquid cooling system is a first multi-chip module to be cooled by the liquid cooling system, the liquid cooling system further comprising a second passive cold plate having a first major surface positioned opposite and spaced apart from the second major surface of the liquid-cooled cold plate, defining a gap therebetween sized to receive a second multi-chip module to be cooled by the liquid cooling system, the second passive cold plate extending from a first end to an opposed second end, wherein one of the opposed condenser blocks defines a recessed slot configured to receive the first end of the second passive cold plate and the other of the opposed condenser blocks defines a recessed slot configured to receive the second end of the second passive cold plate.

3. The liquid cooling system according to claim 2, wherein the first passive cold or the second passive cold plate, or both, is a passive, two-phase cold plate.

4. The liquid cooling system according to claim 3, wherein each passive, two-phase cold plate comprises a condenser region positioned adjacent the first end and the second end of the respective two-phase cold plate and wherein the opposed condenser blocks receive heat from each condenser region.

5. The liquid cooling system according to claim 2, further comprising a clip configured to compress the first and second passive cold plates, the first and second multi-chip modules and liquid-cooled cold plate together.

6. The liquid cooling system according to claim 2, wherein the liquid-cooled cold plate is a first liquid-cooled cold plate, the liquid cooling system further comprising a second liquid-cooled cold plate having an internal passageway fluidically coupled with the opposed condenser blocks.

7. The liquid cooling system according to claim 6, wherein the second liquid-cooled cold plate has a first end and an opposed second end and opposed first and second major surfaces, wherein the internal passageway of the second liquid-cooled cold plate is positioned between the opposed first and second major surfaces of the second liquid-cooled cold plate and extends from the first end of the second liquid-cooled cold plate to the opposed second end of the second liquid-cooled cold plate.

8. The liquid cooling system according to claim 6, further comprising a third passive cold plate having a first major surface positioned opposite and so spaced apart from the first major surface of the second liquid-cooled cold plate as to define a gap sized to receive a third multi-chip module to be cooled by the liquid cooling system.

9. The liquid cooling system according to claim 8, further comprising a fourth passive cold plate having a first major surface positioned opposite and so spaced apart from the second major surface of the second liquid-cooled cold plate as to define a gap sized to receive a fourth multi-chip module to be cooled by the liquid cooling system.

10. The liquid cooling system according to claim 1, further comprising a first thermal interface material positioned in contact with first major surface major surface of the passive cold plate, and a second thermal interface material positioned in contact with the first major surface of the liquid-cooled cold plate, wherein the first thermal interface material and the second thermal interface material are configured to provide thermal contact between opposed faces of the multi-chip module to be cooled by the cooling system and the respective first major surfaces of the passive cold plate and the liquid-cooled cold plate.

11. The liquid cooling system according to claim 10, wherein one of the first thermal interface material and the second thermal interface material comprises a bonding agent that bonds the first major surface major surface of the respective cold plate with the multi-chip module to be cooled by the cooling system.

12. A hybrid cooler, comprising:
a first condenser block and a second condenser block;
a liquid-cooled cold plate having opposed first and second external major surfaces and an internal passageway to direct a flow of coolant through the liquid-cooled cold plate to cool the opposed first and second external major surfaces, the internal passageway being fluidically coupled with the first condenser block and the second condenser block;
a first passive cold plate and a second passive cold plate, each of the first passive cold plate and the second passive cold plate extending from the first condenser block to the second condenser block, each of the first passive cold plate and the second passive cold plate having a respective major surface positioned opposite the opposed first and second external major surfaces of the liquid-cooled cold plate, wherein the liquid-cooled cold plate is positioned between the first passive cold plate and the second passive cold plate.

13. The hybrid cooler according to claim 12, wherein the first passive cold plate is so spaced apart from the liquid-cooled cold plate as to define a first gap therebetween, wherein the second passive cold plate is so spaced apart from the liquid-cooled cold plate as to define a second gap therebetween, wherein the first gap and the second gap are so sized as to receive a first multi-chip module and a second multi-chip module, respectively.

14. The hybrid cooler according to claim 12, wherein the liquid-cooled cold plate is a first liquid-cooled cold plate, the hybrid cooler further comprising a second liquid-cooled cold plate and a third passive cold plate.

15. The hybrid cooler according to claim 14, wherein the second liquid-cooled cold plate is positioned between the third passive cold plate and one of the first passive cold plate and the second passive cold plate.

16. The hybrid cooler according to claim 15, wherein the third passive cold plate is so spaced apart from the second liquid-cooled cold plate as to define a gap therebetween, wherein the gap is so sized as to receive a multi-chip module.

17. The hybrid cooler according to claim 14, further comprising a fourth passive cold plate so spaced apart from the second liquid cooler as to define a gap therebetween, the gap being sized to receive a multi-chip module.

18. The hybrid cooler according to claim 12, wherein the first condenser block comprises an inlet port and the second condenser block comprises an outlet port.

19. The hybrid cooler according to claim 18, wherein the inlet port is a first inlet port, the first condenser block further comprising a second inlet port.

20. The hybrid cooler according to claim 18, wherein the outlet port is a first outlet port, the second condenser block further comprising a second outlet port.

21. The hybrid cooler according to claim 18, wherein the first condenser block further comprises an outlet port.
